(19) United States
(12) Patent Application Publication
(10) Pub. No.: US 2025/0379053 A1
(43) Pub. Date: Dec. 11, 2025

(54) METHOD FOR ETCHING A METAL HARD MASK

(71) Applicant: Tokyo Electron Limited, Tokyo (JP)

(72) Inventor: Joshua Baillargeon, Albany, NY (US)

(21) Appl. No.: 18/734,683

(22) Filed: Jun. 5, 2024

(51) Int. Cl. H01L 21/033

(52) U.S. Cl. CPC H01L 21/0337

(57) ABSTRACT

A method for forming a semiconductor device can include receiving a substrate having a metal mask layer thereon and a first mask layer over the metal mask layer, where the first mask layer is patterned having holes that open to the metal mask layer, and where the metal mask layer contains tungsten, silicon, and nitrogen, passivating a surface of the metal mask layer in the holes using a first chemistry to form a passivation layer on the surface of the metal mask layer, where the first chemistry contains sulfur and hydrogen, and performing an anisotropic etch with a second chemistry to remove first passivation portions of the passivation layer and first metal portions of the metal mask layer at bottoms of the holes to increase hole depths of the holes in the metal mask layer, and where the second chemistry contains boron and chlorine.

### TECHNICAL FIELD

The present disclosure relates generally to methods for manufacturing semiconductor devices, and more particularly, processes for etching metal hard masks for manufacturing semiconductor devices.

### BACKGROUND

Various metal materials have been used for metal hard masks, which can be used for forming structures and features such as capacitors for dynamic random access memory (DRAM) devices. Typically, before a high aspect ratio feature, such as a high aspect ratio contact (HARC), can be etched and formed in a semiconductor material, a hard mask is first formed and patterned over the semiconductor material.

A metal hard mask is typically more resistant to etchants used for etching the underlying semiconductor materials. The enhanced etch selectivity allows for the metal hard mask to provide controlled and precise patterning while etching the underlying semiconductor material. Additionally, this can provide better control over critical dimensions, especially when forming high aspect ratio features that require high precision.

The material for a metal hard mask is typically selected based on its compatibility with the later semiconductor processing steps when using the metal hard mask to pattern and etch the underlying semiconductor materials, such as etch chemicals, temperature, plasma, and ion bombardment (e.g., during reactive ion etching or RIE). A metal hard mask can endure the semiconductor processing conditions while maintaining its critical dimensions and sufficient thickness for reaching high aspect ratios while etching the underlying semiconductor materials through the metal hard mask structure.

And because the metal hard mask is the mask for forming semiconductor structures and patterns, the critical dimensions obtained during the formation of the metal hard mask require precision and uniformity for achieving high-quality and smaller scaled dimensions (i.e., greater device density) for the semiconductor device being made. As size and geometry scaling continues to shrink in semiconductor devices, new materials are tested and developed for metal hard masks, as well as new etching chemistries and conditions for new and currently-used metal hard mask materials and/or new or currently-used etching equipment. And as size and geometry continue to scale to smaller dimensions and/or deeper contacts for the semiconductor devices, new etching chemistries and processes are needed to allow for target critical dimensions and pattern uniformity to be achieved while making a metal hard mask.

### SUMMARY

In accordance with an embodiment of the present disclosure, a method for forming a semiconductor device can include: receiving a substrate having a metal mask layer thereon and a first mask layer over the metal mask layer, where the first mask layer is patterned having holes that open to the metal mask layer, and where the metal mask layer contains tungsten, silicon, and/or nitrogen, or alternatively the metal mask layer contains tungsten and nitrogen (WxN) (without silicon); passivating a surface of the metal mask layer in the holes using a first chemistry to form a passivation layer on the surface of the metal mask layer, where the first chemistry contains sulfur and hydrogen, or alternatively the first chemistry contains sulfur, oxygen, and hydrogen; and performing an anisotropic etch with a second chemistry to remove first passivation portions of the passivation layer and first metal portions of the metal mask layer at bottoms of the holes to increase hole depths of the holes in the metal mask layer, and where the second chemistry contains boron and chlorine.

In accordance with an embodiment of the present disclosure, a method for forming a semiconductor device can include: depositing a metal mask layer over a substrate, where the metal mask layer contains tungsten, silicon, and/or nitrogen; depositing a first mask layer over the metal mask layer; patterning and etching the first mask layer to form holes in the first mask layer, where the holes open to the metal mask layer; performing a first anisotropic etch to remove first metal portions of the metal mask layer at first bottoms of the holes to increase to first hole depths of the holes in the metal mask layer; passivating a surface of the metal mask layer in the holes using a first chemistry to form a passivation layer on the surface of the metal mask layer, where the first chemistry contains sulfur, oxygen, and hydrogen; performing a second anisotropic etch with a second chemistry to remove first passivation portions of the passivation layer and second metal portions of the metal mask layer at second bottoms of the holes to increase to second hole depths of the holes in the metal mask layer, where second passivation portions of the passivation layer remain on at least part of sidewalls of the holes after the second anisotropic etch, where the second chemistry contains boron and chlorine, and where the second hole depths are greater than the first hole depths; and sequentially repeating the passivating with the first chemistry to form the passivation layer and the performing of the second anisotropic etch with the second chemistry until the holes open to the substrate through the metal mask layer.

In accordance with an embodiment of the present disclosure, a method for forming a semiconductor device can include: providing a substrate having a first intermediate structure of a metal hard mask structure formed over the substrate, where the first intermediate structure includes a metal mask layer and a first mask layer formed over the metal mask layer, where the first mask layer of the first intermediate structure is patterned to have holes through the first mask layer and partially into to the metal mask layer, where the metal mask layer contains W(Si) N; passivating first exposed surfaces of the metal mask layer in the holes using a first chemistry to form first passivation layers on the first exposed surfaces of the metal mask layer, where the first chemistry is formed by flowing a first gas mixture containing SO₂ and H₂; and performing a first anisotropic etch with a second chemistry to remove first passivation portions of the first passivation layers and first metal portions of the metal mask layer at first bottoms of the holes to form first hole depths of the holes in the metal mask layer, where second passivation portions of the first passivation layers remain on at least part of sidewalls of the holes after the first anisotropic etch, to form a second intermediate structure of the metal hard mask structure, where the second chemistry is formed by flowing a second gas mixture containing BCl₃ and Cl₂.

In accordance with an embodiment of the present disclosure, a method for selecting manufacturing parameters for forming a semiconductor device can include: selecting a first material composition for a metal mask layer, where the metal mask layer contains tungsten, silicon, and nitrogen; selecting a first parameter set including a first gas flow mixture of a first chemistry and a second gas flow mixture of a second chemistry, where the first chemistry contains sulfur, oxygen, and hydrogen, and where the second chemistry contains boron and chlorine; forming, patterning, and etching the metal mask layer to form a feature set in the metal mask layer using the first parameter set, where the forming, patterning, and etching the metal mask layer to form the feature set comprises sequentially repeating a forming of a passivation layer using the first chemistry and etching the metal mask layer using the second chemistry; changing the first parameter set to a second parameter set by adjusting one of or both of the first gas flow mixture for the first chemistry and the second gas flow mixture for the second chemistry, based on a first result of the feature set obtained using the first parameter set; and repeating the forming, patterning, and etching the metal mask layer to form the feature set using the second parameter set.

The method for selecting manufacturing parameters for forming a semiconductor device can further include: changing the first material composition to a second material composition for the metal mask layer, based on a second result of the feature set obtained using the second parameter set; repeating the forming, patterning, and etching the metal mask layer to form the feature set using the second parameter set and the second material composition for the metal mask layer; changing the second parameter set to a third parameter set by adjusting one of or both of the first gas flow mixture for the first chemistry and the second gas flow mixture for the second chemistry, based on a third result of the feature set obtained using the second parameter set and the second material composition for the metal mask layer; and repeating the forming, patterning, and etching the metal mask layer to form the feature set using the third parameter set and the second material composition for the metal mask layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a top view of a metal hard mask structure made according to some embodiments of the present disclosure;

FIGS. 2-11 are enlarged cross-section views illustrating intermediate structures of a metal hard mask structure made according to some embodiments of the present disclosure;

FIG. 12 is an enlarged cross-section view of the metal hard mask structure of FIG. 1 taken along line A-A and made according to some embodiments of the present disclosure;

FIG. 13 illustrates a flow chart implementing the etching of a metal hard mask in accordance with an embodiment of the present disclosure;

FIG. 14 illustrates a flow chart implementing the etching of a metal hard mask in accordance with an embodiment of the present disclosure;

FIG. 15 illustrates a flow chart implementing the etching of a metal hard mask in accordance with an embodiment of the present disclosure; and

FIG. 16 illustrates a flow chart implementing the etching of a metal hard mask in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

In some embodiments of the present disclosure, a method for forming a semiconductor device includes providing a substrate having a metal mask layer and a first mask layer over the metal mask layer, where the first mask layer has holes opening to the metal mask layer, and where the metal mask layer contains tungsten combined with silicon and/or nitrogen, passivating a surface of the metal mask layer in the holes using a first chemistry to form a passivation layer, where the first chemistry contains a sulfur-containing gas and a hydrogen-containing gas (e.g., SO₂, H₂S, H₂, COS), and anisotropically etching with a second chemistry to remove a portion of the passivation layer and a portion of the metal mask layer at bottoms of the holes, where the second chemistry contains a boron-containing gas and a chlorine-containing gas (e.g., BCl₃, Cl₂, diborane). In some embodiments, the passivating to form the passivation layer and the etching to remove the passivation layer may be sequentially repeated and cycled until a desired depth of the holes is achieved. Some example embodiments of the present disclosure are described in more detail below with reference to the drawings of the present disclosure, to describe some example variations for some embodiments of the present disclosure. Other embodiments can also be understood from the entirety of the specification and the claims filed herein.

In the present disclosure, terms such as “first”, “second”, “third”, “fourth”, and the like, may be used to describe various components, but the components are not necessarily limited by such terms, for example, regarding nature, order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure, certain elements may be discussed, referred to, and actually plural, but only shown as a singular example in the drawings, even though that single example is among a set of a plurality. Similarly, certain elements may be discussed, referred to, and shown as singular, but may be plural or may be part of a set of a plurality of the same. Given that a structure and feature is typically repeated many times in a semiconductor device, one of ordinary skill in the art to which the present disclosure pertains can realize and understand such alternating between singular and plural.

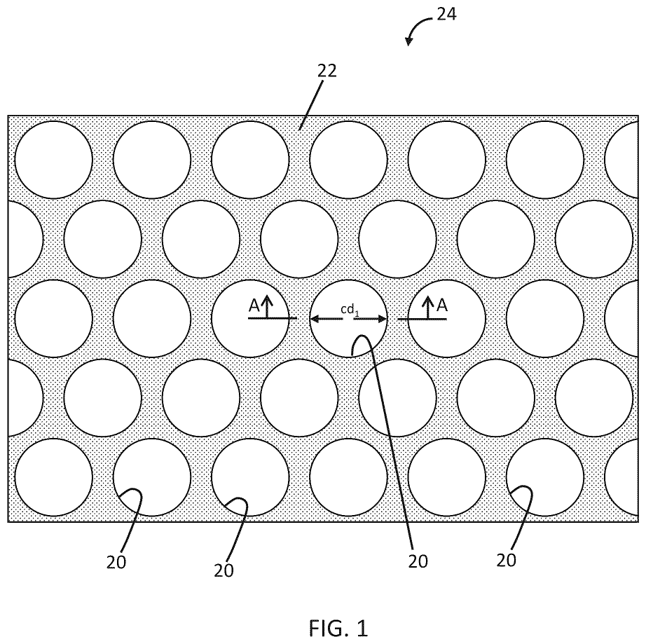

For simplification and illustration purposes, FIGS. 1 to 12 are merely showing some portions of a substrate and of intermediate structures for a semiconductor device that can be relevant to a method of making a semiconductor device according to some embodiments of the present disclosure. Accordingly, in FIGS. 1 to 12, to simplify the drawings, as can be readily understood by one of ordinary skill in the pertinent art, additional layers and structures for a semiconductor device made before, under, below, or adjacent the intermediate structures shown in the drawings can be omitted and not shown. And accordingly, in FIGS. 1 to 12, to simplify the drawings, as can be readily understood by one of ordinary skill in the pertinent art, additional layers and structures for a semiconductor device made after, over, above, or adjacent the intermediate structures shown in the drawings can be omitted and not shown. Furthermore, in an actual completed semiconductor device cross-section, the intermediate structures, or remnants thereof, that are illustrated and represented in the drawings of the present disclosure in a simplified manner as having squared edges, rectangular block shapes, and/or linear shapes can be actually pointed (e.g., bottoms of the holes), more rounded, more curved shaped, and less linear shaped.

FIGS. 1 to 12 are various views of various intermediate structures of an example semiconductor device, schematically showing a processing sequence for forming the intermediate structures of the example semiconductor device using methods according to some embodiments of the present disclosure. In FIGS. 1 to 12, the example semiconductor device being built includes holes 20 being formed in a metal mask layer 22 of a metal hard mask structure 24 for making capacitors for dynamic random access memory (DRAM). However, some embodiments of the present disclosure can be applied to making other types or portions of intermediate structures for other types and kinds of semiconductor devices.

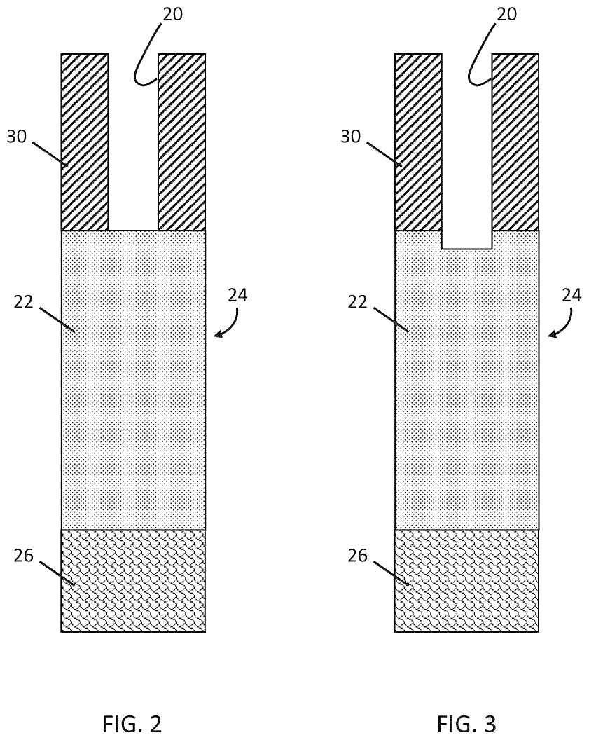

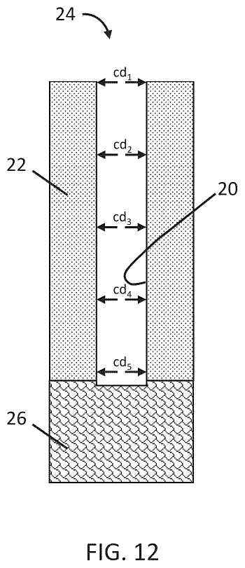

More specifically, FIG. 1 is a top view of a completed metal hard mask structure 24 made according to some embodiments of the present disclosure, which can be ready for subsequent processing operations to form holes in the underlying substrate 26 using the completed metal hard mask structure 24. FIGS. 2 to 12 are cross-section views taken from a perspective of line A-A in FIG. 1, illustrating intermediate structures of a metal hard mask structure 24 for the example semiconductor device being made in an example sequence using methods according to some embodiments of the present disclosure. FIG. 12 is an enlarged cross-section view of the completed metal hard mask structure 24 of FIG. 1 taken along line A-A and made according to some embodiments of the present disclosure.

Referring to FIG. 1, a metal hard mask structure 24 can have a set of holes 20 formed in and through a metal mask layer 22. The holes 20 can be arranged in a honeycomb or hexagon pattern, for example, which is typically used to allow for greater density and holes per area, which can be for forming high aspect ratio contacts for DRAM, for example. In other embodiments (not shown), the holes can be arranged in a square or grid pattern, for example. For simplification, only some holes 20 are shown in FIG. 1. One of ordinary skill in the art can understand that in an actual semiconductor device, such metal hard mask structure 24 can have many more holes and/or patterned features (not shown).

Referring to FIGS. 2-12, next an example and simplified sequence for forming the completed metal hard mask structure 24 shown in FIGS. 1 and 12 will be described as an example use of some method embodiments of the present disclosure. While making an actual metal hard mask structure for making an actual semiconductor device, there can be many more operations in the sequence, and accordingly many more intermediate structures in the sequence. Thus, some operations of the overall sequence can be omitted because they are repeats of operations already described, as can be apparent to one of ordinary skill in art to which the present disclosure pertains.

Referring to FIG. 2, a first mask layer 30 can be formed over a metal mask layer 22. The metal mask layer 22 can be formed over a substrate 26 for a semiconductor device. The first mask layer 30 can be formed directly on the metal mask layer 22, or there can be one or more intervening layers (not shown) between the first mask layer 30 and the metal mask layer 22. Even though the first mask layer 30 is illustrated and represented in the drawings as a single layer of one material, in some embodiments, the first mask layer 30 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the first mask layer 30 can be a dielectric material or include a set of dielectric materials, such as silicon dioxide (e.g., tetraethylorthosilicate (TEOS)), silicon oxynitride (SiON), silicon nitride (SiN), or any combination thereof, for example. In some embodiments, the first mask layer 30 can be formed using physical vapor deposition (PVD), chemical vapor deposition (CVD), plasma-enhanced chemical vapor deposition (PECVD), atomic layer deposition (ALD), plasma-enhanced atomic layer deposition (PEALD), or any combination thereof, for example.

In some embodiments, the metal mask layer 22 can contain tungsten and silicon, such as a tungsten silicide. In some embodiments, the metal mask layer 22 can contain tungsten, silicon, and nitrogen, such as W(Si) N. Even though the metal mask layer 22 is illustrated and represented in the drawings as a single layer of one material, in some embodiments, the metal mask layer 22 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the metal mask layer 22 can be formed using PVD, CVD, PECVD, ALD, PEALD, or any combination thereof, for example. In some embodiments, the metal mask layer 22 can be W(Si) N formed using PVD, for example. In some embodiments, the metal mask layer 22 can contain 55-70% tungsten, in terms of atomic percentages for atomic composition. In some embodiments, the metal mask layer 22 can contain 4-26% silicon, in terms of atomic percentages for atomic composition. In some embodiments, the metal mask layer 22 can contain 10-40% nitrogen, in terms of atomic percentages for atomic composition. More details regarding the composition of the metal mask layer 22 and some experimental results for some variations on the composition of the metal mask layer 22 will be described below.

The substrate 26 can be a semiconductor material or a combination of semiconductor materials, such as silicon nitride (SiN), silicon oxynitride (SiON), silicon carbonitride (SiCN), silicon dioxide (SiO₂), silicon, silicon germanium, silicon carbide, or any combination thereof, for example. The substrate 26 can be part of any suitable wafer type or structure, including a silicon wafer or a silicon-on-insulator (SOI) wafer, for example. The metal mask layer 22 can formed directly on the substrate 26, or there can be one or more intervening layers between the metal mask layer 22 and the substrate 26, for example.

Still referring to FIG. 2, the first mask layer 30 shown in this intermediate structure can be already patterned with holes 20 through the first mask layer 30 that open to the metal mask layer 22. At the holes 20, corresponding surfaces of the metal mask layer 22 can be exposed through the holes 20. In FIG. 2, one example hole 20, among the holes in the first mask layer 30, is shown. Similarly, one example surface of the metal mask layer 22 in the one example hole 20, among the surfaces on the metal mask layer 22 in the holes, is shown in FIG. 2. During subsequent operations described with reference to FIGS. 3 to 11, leading to the intermediate structure of FIG. 12, surfaces of the metal mask layer 22 are exposed via the holes 20 formed in the first mask layer 30, with a goal to extend the holes 20 into the metal mask layer 22 with uniform critical dimensions resulting along different hole depths of the holes, and uniformly and consistently among the many holes being formed across the wafer.

Referring to FIG. 3, an initial etch of the metal mask layer 22 can be performed to begin extending the hole 20 into the metal mask layer 22 or begin forming a new hole in the metal mask layer 22 for patterning the metal mask layer 22 (and in a broader context, beginning the extending of the plurality of holes into the metal mask layer or beginning the formation of a plurality of new holes in the metal mask layer). In some embodiments, this initial etch can be an anisotropic etch. In some embodiments, this initial etch can be a reactive ion etching (RIE) configured so that most of the ions bombard the metal mask layer 22 with ions traveling perpendicular to a top surface of the metal mask layer 22 and the wafer, which can help the ions reach the bottom of the hole 20. In some embodiments, this initial etch can use an initial etch chemistry containing chlorine (Cl₂) with a carrier gas of argon (Ar), for example.

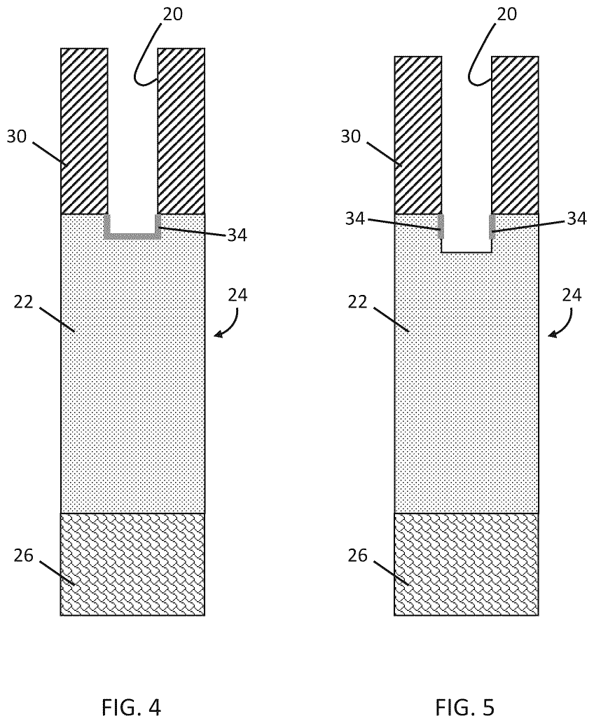

Referring to FIG. 4, an exposed surface of the metal mask layer 22 shown in FIG. 3 can be passivated, via the hole 20 formed in the first mask layer 30, using a first chemistry to form a passivation layer 34 on the surface of the metal mask layer 22. In some embodiments, the passivation layer can contain tungsten and sulfur. In some embodiments, the passivation layer can a mix or combination of several materials formed, such as SO, WSₓ, SiSₓ, WOₓ, SiOₓ, WSO with SiSO (e.g., in a case of WSi), WNS with SiNS (e.g., in a case of WSiN), or any combination thereof, for example. In some embodiments, the first chemistry can be selective to react or bond stronger with the metal mask layer 22 than with the first mask layer 30. In some embodiments, the first chemistry can contain sulfur-containing gas and hydrogen-containing gas. In some embodiments, the first chemistry can contain sulfur and hydrogen. In some embodiments, the first chemistry can contain sulfur, oxygen, and hydrogen. In some embodiments, the first chemistry can be formed by flowing a halogen-free sulfur containing gas. In some embodiments, the first chemistry can be formed by flowing a gas mixture containing sulfur dioxide (SO₂) and hydrogen (H₂). In some embodiments, the passivation layer 34 can be conformally formed on a surface of the metal mask layer 22 via the hole 20. In some embodiments, the passivation layer can be formed through a reactive ion etch (RIE) or in RIE conditions utilizing gases that are unable to etch, or minimally etch, the metal but that can aid in modifying the surface for protection by forming the passivation layer on the exposed surface. In some embodiments, the passivation layer can be formed with or without using or forming a plasma while using or flowing gases of the first chemistry. In some embodiments, the flowrates, ratios, and conditions for implementing the first chemistry can be varied. More details regarding the first chemistry and some experimental results for some variations on flowrates, ratios, and conditions will be described below.

Referring to FIG. 5, a first passivation portion of the passivation layer 34 and a first metal portion of the metal mask layer 22 can be removed in the hole 20 by performing an anisotropic etch with a second chemistry to extend the hole 20 and increase a hole depth of the hole 20 in the metal mask layer 22 (and in a broader context, extending the plurality of holes in the metal mask layer and increasing hole depths of the plurality of holes in the metal mask layer) to form an updated intermediate structure for the metal hard mask structure 24. In some embodiments, the anisotropic etch can be reactive ion etching (RIE) (utilizing a plasma source) configured so that most of the ions bombard the passivation layer 34 and the metal mask layer 22 with ions traveling perpendicular to a top surface of the substrate 26, which can help the ions reach the bottom of the hole 20. In such case, due to the nature and action of RIE and the vectors of the ions, part of or a portion of the passivation layer 34 can be removed mostly at the bottom of the hole 20 such that some of the passivation layer 34 remains on sidewalls of the hole 20 on the surface of the metal mask layer 22, as illustrated in FIG. 5 for example. In an actual intermediate structure of the simplified intermediate structure illustrated in FIG. 5, the etching can form a pointed shape or rounded shape at the bottom of the hole, and remaining portions of the passivation layer can be pitted, irregular shaped, varying in thickness, tapering in thickness (thinner towards the bottom of the hole), or any combination thereof, for example.

After the anisotropic etch using the second chemistry, second passivation portions of the passivation layer 34 can remain on at least part of sidewalls of the hole 20, as illustrated in FIG. 5 for example. Thus, the passivation layer 34 being formed on the sidewalls of the hole 20 in the metal mask layer 22 can provide protection (acting as a passivation or protection layer) against the anisotropic etching attacking and laterally etching the sidewalls of the hole 20 while vertically etching the bottom of the hole 20 to extend the hole depth of the hole in the metal mask layer 22 (and in a broader context, protecting sidewalls of the plurality of holes from lateral etching while vertically etching bottoms of the plurality of holes to extend hole depths of the plurality of holes in the metal mask layer).

In some embodiments, the second chemistry can be selective to etch the metal mask layer 22 stronger (more, faster) than the passivation layer 34 and the first mask layer 30. In some embodiments, the second chemistry can contain boron and chlorine. In some embodiments, the second chemistry can be formed by flowing a gas mixture containing contain boron trichloride (BCl₃) and chlorine (Cl₂). In some embodiments, the flowrates, ratios, and conditions for implementing the second chemistry can be varied. More details regarding the second chemistry and some experimental results for some variations on flowrates, ratios, and conditions will be described below. In some embodiments, the initial etch chemistry for the initial etch referenced above regarding FIG. 3, can use the second chemistry.

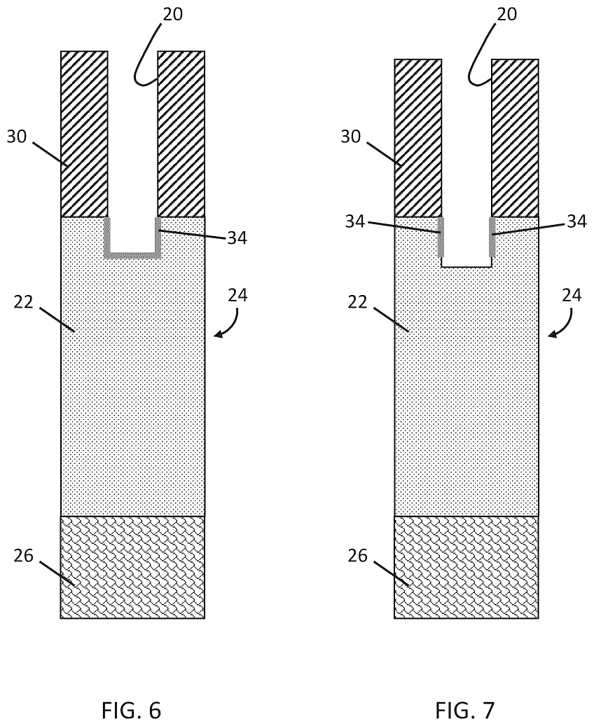

Referring to FIG. 6, an exposed surface of the metal mask layer 22 shown in FIG. 5 can be passivated, via the hole 20 formed in the first mask layer 30, using the first chemistry to form a passivation layer 34 on the exposed surface of the metal mask layer 22. The operation to form the intermediate structure illustrated in FIG. 6 can be a repeat of the operation described above regarding FIG. 4. The second portions of the passivation layer 34 remaining in FIG. 5 after the anisotropic etch (e.g., etch using the second chemistry) can be combined with third (new) portions of passivation layer to form a total passivation layer, such as the passivation layer 34 shown in FIG. 6. The third (new) portions of the passivation layer 34 can form on the exposed surfaces of the metal mask layer 22, as well as on the remaining portions (second portions) of the prior formed passivation layer on the surface of the metal mask layer. Although the passivation layer 34 in FIG. 6 is shown as a single uniform layer of a single material (for simplification of illustration), the actual passivation layer illustrated in FIG. 6 can include new portions of the passivation layer formed using the first chemistry combined with older remaining portions of the passivation layer (after prior etches, e.g., etches using the second chemistry) from prior passivations using the first chemistry, which can become multiple laminates of the prior passivation layers at some places as the number of cycles increases, for example. Thus, the passivation layer 34 can be a composite of new passivation layer portions formed on newly exposed surfaces of the metal mask layer 22 (e.g., after an immediately prior vertical anisotropic etching operation using the second chemistry) using the first chemistry, combined with one or more prior passivation layers formed during one or more prior passivations of one or more prior exposed surfaces of the metal mask layer at different times from different operations, also deposited using the first chemistry.

Referring to FIG. 7, portions of the passivation layer 34 and portions of the metal mask layer 22 can be removed in the bottom of the hole 20 by performing an anisotropic etch with a second chemistry to extend the hole and increase a hole depth of the hole in the metal mask layer (and in a broader context, vertically extending the plurality of holes in the metal mask layer and increasing hole depths of the plurality of holes in the metal mask layer) to form an updated intermediate structure for the metal hard mask structure 24. After the anisotropic etch using the second chemistry, portions of the passivation layer 34 can remain on at least part of sidewalls of the hole 20, as illustrated in FIG. 7 for example. The operation to form the intermediate structure illustrated in FIG. 7 can be a repeat of the operation described above regarding FIG. 5.

The operations resulting in the intermediate structures of the metal hard mask structure 24 illustrated in FIGS. 6 and 7 can be repeats of the operations described above relating to FIGS. 4 and 5, respectively. In some embodiments, the operations of passivating the exposed surfaces of the metal mask layer 22 in the holes 20 to form passivation layers 34 on those exposed surfaces and anisotropically etching to remove at least part of the passivation layers and portions of the metal mask layer, mostly at the bottoms of the holes, can be sequentially repeated and cycled many times until desired hole depths of the holes are achieved and/or until the holes open to the underlying substrate 26 (as illustrated in FIG. 12).

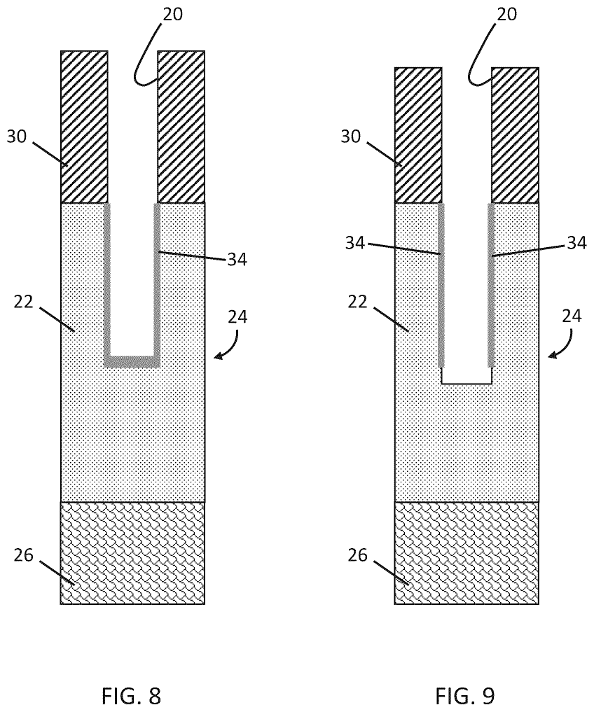

Referring to FIG. 8, an exposed surface of the metal mask layer 22 can be passivated, via the hole 20 formed in the first mask layer 30, using the first chemistry to form a passivation layer 34 on the surface of the metal mask layer 22. The operation to form the intermediate structure of the metal hard mask structure 24 illustrated in FIG. 8 can be a repeat of the operation described above regarding FIGS. 4 and 6.

There can be one or more sequentially repeated or cycled operations of the passivating and etching between the intermediate structure illustrated in FIG. 7 and the intermediate structure illustrated in FIG. 8. Thus, the jump in hole depth illustrated in FIG. 7 to the deeper hole depth illustrated in FIG. 8 can be due to one or more additional cycles of passivating and etching, with such jump in the sequence being for purposes of simplifying the illustrations of the sequence of intermediate structures being formed.

The passivation layer 34 in FIG. 8 can include portions of the passivation layer from one or more prior operations that were not removed during the prior etching operations. For simplification, the passivation layer 34 is illustrated in FIG. 8 as a single uniform layer. In an actual intermediate structure, the passivation layer 34 illustrated in FIG. 8 can include multiple parts or portions from multiple prior operations of passivating to form the passivation layer. During the passivating to form the passivation layer 34 using the first chemistry, as described above regarding FIGS. 4 and 6, the exposed and unpassivated surface of the metal mask layer can be passivated to form new portions of the passivation layer on the surfaces of the metal mask layer 22 (via the hole 20) to protect the sidewalls of the hole 20 from ion bombardment with the passivation layer.

Referring to FIG. 9, portions of the passivation layer 34 and portions of the metal mask layer 22 can be removed in the bottom of the hole 20 by performing an anisotropic etch with a second chemistry to extend the hole and increase a hole depth of the hole in the metal mask layer (and in a broader context, vertically extending the plurality of holes in the metal mask layer and increasing hole depths of the plurality of holes in the metal mask layer) to form an updated intermediate structure for the metal hard mask structure 24. After the anisotropic etch using the second chemistry, portions of the passivation layer 34 can remain on at least part of sidewalls of the hole 20, as illustrated in FIG. 9 for example. The operation to form the intermediate structure of the metal hard mask structure 24 illustrated in FIG. 9 can be a repeat of the operation described above regarding FIGS. 5 and 7.

The operations resulting in the intermediate structures of the metal hard mask structure 24 illustrated in FIGS. 8 and 9 can be repeats of the operations described above relating to FIGS. 4 and 5, respectively, and/or FIGS. 6 and 7, respectively. There can be multiple sequentially repeated or cycled operations of the passivating and etching between the intermediate structure illustrated in FIG. 7 and the intermediate structure illustrated in FIG. 8. Thus, the jump in hole depth illustrated in FIG. 7 to deeper hole depth illustrated in FIG. 8 can be due to multiple cycles of passivating and etching, with such a jump in the sequence being for purposes of simplifying the illustrations of the sequence of intermediate structures being formed.

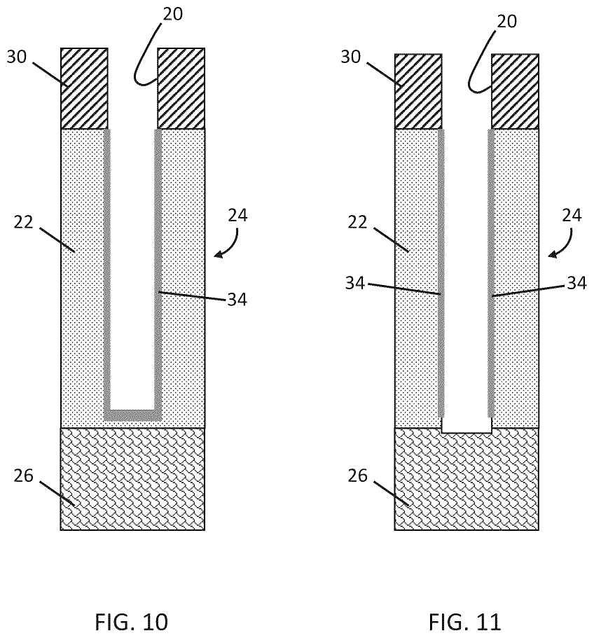

Referring to FIG. 10, an exposed surface of the metal mask layer 22 can be passivated, via the hole 20 formed in the first mask layer 30, using the first chemistry to form a passivation layer 34 on the surface of the metal mask layer. The operation to form the intermediate structure illustrated in FIG. 10 can be a repeat of the operation described above regarding FIGS. 4, 6, and 8.

Referring to FIG. 11, portions of the passivation layer 34 and portions of the metal mask layer 22 can be removed in the bottom of the hole 20 by performing an anisotropic etch with a second chemistry to extend the hole and increase a hole depth of the hole in the metal mask layer (and in a broader context, vertically extending the plurality of holes in the metal mask layer and increasing hole depths of the plurality of holes in the metal mask layer) to form an updated intermediate structure for the metal hard mask structure 24. After the anisotropic etch using the second chemistry, portions of the passivation layer 34 can remain on at least part of sidewalls of the hole 20, as illustrated in FIG. 11 for example. The operation to form the intermediate structure illustrated in FIG. 11 can be a repeat of the operation described above regarding FIGS. 5, 7, and 9.

At this stage illustrated in FIG. 11, the etching can be continued until the hole 20 in the metal mask layer 22 opens to the underlying substrate 26 (and in a broader context, continuing the etching until the holes or most all of the holes in the metal mask layer open to the underlying substrate). In some embodiments, the etching of the metal mask layer 22 can over etch (i.e., not stopping precisely at the top surface of the substrate 26) to begin forming the hole 20 in the substrate 26, as illustrated in FIG. 11 (and in a broader context, over etching can form corresponding holes in the underlying substrate through at least some of the holes formed in the metal mask layer).

In an actual intermediate structure, due to some inherent non-uniformity across the wafer or among some portions of the pattern or among some portions of the wafer, some holes can barely open to the substrate, some holes can sufficiently open to the substrate and stop short of forming holes in the substrate (e.g., etching stopping on the top surface of the substrate), and some holes can over etch to begin forming corresponding holes in the underlying substrate. The amount and extent for which the underlying substrate 26 is etched while sufficiently opening the hole 20 of the metal mask layer 22 to the substrate can depend on the shape of the etch front at the bottom of the hole. In some embodiments, the second chemistry can be selective to etch the metal mask layer 22 stronger (more, faster) than the substrate 26 or an etch stop layer (not shown) located between the metal mask layer and the substrate. In some embodiments, depending on the material of the substrate 26 (or underlying layer) (e.g., SiO₂ versus SiN), the etch can stop on the substrate without significantly etching it due to the selectivity to the etch chemistry being used to etch the metal. Such etch selectivity can actually help in opening or enlarging the bottom critical dimension (CD) of the hole being formed in the metal mask layer 22.

Referring to FIG. 12, the first mask layer can be removed, such as by using chemical mechanical polishing (CMP), for example. In some embodiments, the first mask layer 30 can be removed during subsequent etching of the substrate 26, such as when the first mask layer is a same or similar material as the substrate (e.g., SiO₂ or SiN) (and thus, a separate operation or step to remove the first mask layer specifically may not be needed). In some embodiments, the first mask layer can remain, fully or partially, during some subsequent operations of using the metal hard mask structure for patterning and etching the underlying substrate. Most of or all of the remaining portions of the passivation layer can be removed, as illustrated in FIG. 12. The remaining portions of the passivation layer on the sidewalls of the holes in the metal mask layer can be removed by continued etching, isotropically and/or anisotropically, using the second chemistry. Optionally, alternatively, or in addition, the holes 20 of the metal mask layer 22 can be cleaned using a hydrofluoric acid (HF) or diluted hydrofluoric acid (DHF), for example. For example, in some embodiments, a subsequent etching of the substrate 26 can proceed without cleaning the holes 20 of the metal mask layer 22 because it may not be necessary as an operation or step during manufacturing of some devices/structures. In some embodiments, part of the passivation layer can remain in the holes of the metal mask layer during some subsequent operations of using the metal hard mask structure for patterning and etching the underlying substrate.

Referring to FIGS. 1 and 12, at the completion of forming a metal hard mask structure 24, a goal can be to have uniform and consistent critical dimensions for the holes 20, in terms of uniformity among all the holes across the wafer, uniformity for the circularity of the holes, and uniformity at different depths of the holes. For example, FIG. 12 illustrates five critical dimension measurements cd₁, cd₂, cd₃, cd₄, and cd₅ for diameter measurements of the hole 20 at varying depths. A goal can be that all of these critical dimensions cd₁, cd₂, cd₃, cd₄, and cd₅ are close to being the same, or within some specified acceptable variation for manufacturing. In an actual hole in an actual metal hard mask structure, there can be some variations in these critical dimensions cd₁, cd₂, cd₃, cd₄, and cd₅. Using some embodiments of the present disclosure, experimental testing has shown that good results can be achieved for uniformity across the wafer, uniformity for circularity of the holes, and uniformity in critical dimensions at various depths of the holes.

Generally, to achieve the best possible results or optimal results during manufacturing for the critical dimensions of the holes in terms of uniformity at different depths and uniformity across a wafer, the flowrates, ratios, and conditions for implementing the first chemistry and the second chemistry can be varied and tuned through experimentation, and can depend upon the composition of the metal mask layer, the diameter of the holes being formed in the metal mask layer, and the depth of the holes being formed in the metal mask layer.

### Experimental Results

During experiments for a considerable amount of time, some different flowrates, ratios, and conditions for implementing the first chemistry and the second chemistry for some different compositions of the metal mask layer were evaluated, according to some embodiments of the present disclosure. Some of the experimental results from such evaluations will be described next. During experimentation, the methodology and sequence of varying the many parameters for selecting flowrates, ratios, and conditions for the first chemistry and the second chemistry, as well as selecting the composition of the metal mask layer, can vary from what is described here as some example ways of performing the experimentation. Accordingly, the following described methodology and sequence for experimentation and for selecting best parameters for the first chemistry, the second chemistry, and the composition of the metal mask layer are simply an example. One of ordinary skill in the art pertaining to the present disclosure can realize other ways of adjusting the flowrates and ratios of the first chemistry, the second chemistry, and the metal mask layer composition with the benefit of the present disclosure.

In some embodiments, to optimize the flowrates of the gases and ratios of the chemicals in the first chemistry and the second chemistry, the following sequence can be followed. For the sake of discussion in the present disclosure, the flowrates and ratios of the gases for the first chemistry and the second chemistry will be discussed in terms of standard cubic centimeters per minute (SCCM) units. First, a material composition of the metal mask layer can be selected. Second, the flow rate of the sulfur oxide (SO₂) for the first chemistry can be adjusted (e.g., relative to a fixed chlorine flow in the etch step). Third, the flow rate ratio of the boron trichloride (BCl₃) relative to the chlorine (Cl₂) for the second chemistry can be adjusted. Fourth, the flow rate of the hydrogen (H₂) for the first chemistry can be adjusted. These steps can be repeated sequentially or non-sequentially to further tune and adjust the first chemistry and the second chemistry according to some embodiments of the present disclosure. In some embodiments, a different sequence or order of selecting the metal mask layer composition and adjusting flow rates for gases of the first chemistry and the second chemistry, and some selections/adjustments can be done in parallel rather than sequentially.

For example, after optimizing the first chemistry and the second chemistry for a first selected material composition of the metal mask layer, for a given patterning (pattern density) and sizing (diameter, depth) of the holes to be formed in the metal mask layer, the first optimization of the first chemistry and the second chemistry can be tested using the patterning and sizing of the holes on different material compositions of the metal mask layer to assess whether another material composition of the metal mask layer may provide better results. And then, if the selection of the material composition of the metal mask layer is changed, the steps of tuning and adjusting the flowrates and ratios of the first chemistry and second chemistry can be repeated to arrive at a second optimization of the of the first chemistry and the second chemistry, for example.

A problem that can occur during the etching of a metal hard mask layer containing tungsten and silicon, such as a tungsten silicide, is scalloping of the sidewalls of the holes, rather than smooth straight sidewalls. The oxidation process of the tungsten and silicon can help in protecting against chlorine (Cl₂) etching attack or lateral etching at boundaries of the etch profile, and the oxidized layer can act as a passivation layer for the sidewalls of the holes during the anisotropic etching. However, oxidized silicon in the passivation layer of the metal mask layer can volatilize at a much lower temperature than oxidized tungsten, which can result in roughness issues for the sidewalls of the holes being formed in the metal mask layer. Thus, the oxidation of the silicon in prior processes is believed to be a cause of some of the irregularities in the etch profile resulting from prior chemistries for etching metal mask layers containing tungsten and silicon.

In some embodiments, by having the first chemistry containing sulfur dioxide and hydrogen in combination with the second chemistry containing boron trichloride and chlorine, the passivation function for the passivation layer on the sidewalls of the holes during a chlorine-based etching can better protect against the chlorine attacking and laterally etching the sidewalls of the holes while vertically etching to increase the hole depths of the holes being formed in the metal mask layer, as compared to prior best known methods of processing.

By incorporating sulfur-containing gas (e.g., SO₂) in the first chemistry, for example, tungsten sulfide and silicon sulfide can have stability due to having very high boiling points. Thus, forming tungsten sulfide and silicon sulfide can be hard to remove, which can enhance the passivation protection characteristics of the passivation layer (for protecting the sidewalls of the holes). For example, while WSₓ and SiSₓ can form and might, if they do form there can be no volatile byproduct when introducing Cl. For example, when oxidizing the film WOClₓ, WO₂Clₓ, or SiOClₓ can be formed, which can be removed from the films as a result.

To achieve better passivation, use of lower flow rates of sulfur containing gases is effective via use of a longer residence time of the gas in the etch chamber. The longer the gas stays in the chamber, the greater the ability for it to dissociate. Sulfar dioxide (SO₂) usage can have bond cleavage of two S—O bonds to result in elemental sulfur for passivation. To gain sulfur in the passivation layer to help with the passivation function, the SO₂ can be dissociated or cleaved twice, first dissociating to SO and O, and second dissociating between S and O. Flow rate of SO₂ can be optimized, as previously discussed. If too low a flow rate is chosen, residue and clogging of contact holes can be observed, further blocking or creating etch stop within features. For example, such residue can clog the opening of the holes (depending on the hole diameter, for example) to block further etching of the bottoms of the holes, which would not be desirable in most cases. Too little sulfur-containing gas in terms of the ratio of sulfur-containing gas relative to hydrogen-containing gas (e.g., H₂) in the first chemistry can result in undercutting (lateral etching at upper portions of the holes) and bowing (lateral etching of the sidewalls of the holes).

The etching can be mostly provided by the Cl₂ of the second chemistry. For example, Cl₂ and/or BCl₃ can liberate chlorine to etch WSiN. By adding a boron-containing gas (e.g., BCl₃) in the second chemistry for the etching, the boron can help passivate and/or reduce the tungsten and/or silicon to stabilize the solid. Formation of complexes such as BOₓCl_{y} or B₂O₃ can help protect and passivate the surface. If also incorporating nitrogen into the metal mask layer, such as W(Si) N, then the boron and nitrogen can also form some stable boron nitride, which can also help protect and passivate the surface. If the boron-containing gas ratio or flow rate is made too high in the second chemistry, then the second chemistry can start to act as an etch stop rather than an etchant.

During the tuning of the first chemistry for an embodiment, if some pitting is occurring in the sidewalls of the holes in the metal mask layer, it can indicate that there can be some non-uniform formation of the passivation layer or irregular deposition of the passivation layer, and/or it can indicate that too much oxidation of the metal mask layer is occurring. Utilization of hydrogen and the amount of hydrogen in the first chemistry can help with reducing oxidation of the metal mask layer during the deposition of the passivation layer. Hydrogen can act as a reductant both in the plasma bulk and at the surface of the metal mask material. In the plasma, hydrogen can readily scavenge liberated O from SO₂ forming either H₂O (water) or H₂O₂ (hydrogen peroxide), which can minimize oxidation of the WSi(N) film. At the metal surface, hydrogen can also scavenge O to produce the aforementioned chemicals and further reduce W and Si, for example. Hence, the hydrogen may be able to scavenge oxygen from the dissociated or dissociating SO₂ and/or SO in the plasma. There can be some formation of sulfuric acid in the mix as well from the first chemistry. Alternatively or in addition, the hydrogen can reduce or help reduce oxidized tungsten and/or oxidized silicon back to tungsten and/or silicon. Experimental testing has revealed that adding the hydrogen into the first chemistry can produce better hole formation, such as less pitting and roughness of the sidewalls of the holes in the metal mask layer.

If the ratio of flow rate of the hydrogen-containing gas (e.g., H₂) is too high in the first chemistry, the hydrogen-containing gas can cause some removal of the passivation layer and reduce its protection function, and/or can cause less formation of the passivation layer on the sidewalls of the holes in the metal mask layer, either or both of which can result in bowing and lateral etching of the sidewalls of the holes in the metal mask layer, for example. Also, if the ratio of flow rate of the hydrogen-containing gas is too high in the first chemistry, the hydrogen-containing gas can remove oxygen from the silicon dioxide in the first mask layer (which is typically containing a dielectric material such as SiO₂ and/or TEOS), which can reduce the selectivity of etching of the metal mask layer relative to the first mask layer, and/or can modify some of the properties of the first mask layer (which typically includes oxygen in its composition). The hydrogen to can also attack SiN hardmasks as well. The formation of NH₃ can be readily liberated and the Si can be etched in the subsequent step by Cl, for example.

Some experiments tested the passivation and etching using the first chemistry and the second chemistry, respectively, at lower temperatures in the range of 50 to 70 degrees Celsius, for example. However, some experiments showed better results for the passivation and etching using the first chemistry and the second chemistry, respectively, at higher temperatures, with best results in some experiments found at 108-132 degrees Celsius. In other embodiments, the temperature used during the passivation and etching can be varied and adjusted.

In some embodiments, the passivation using the first chemistry can be performed for 7-10 seconds and the etching using the second chemistry can be performed for 16-20 seconds, with 16-20 cycles, for example. This example provides a total time for patterning and etching holes in the metal mask layer in some embodiments can be very similar, within about 10-30 seconds, to that of a conventional process of the prior art. In other embodiments, the passivation and etch times per cycle can be varied and adjusted.

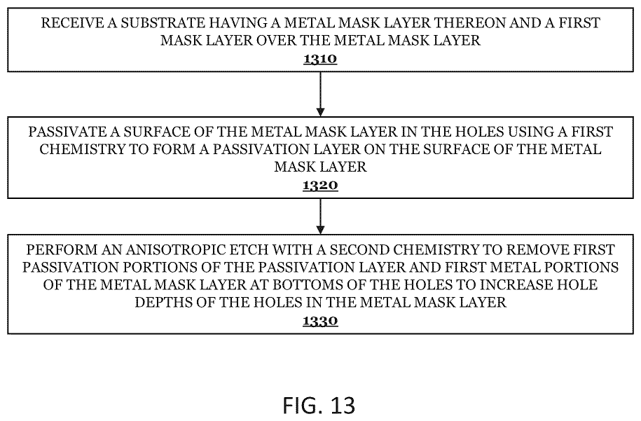

During the experiments using the first chemistry for passivation and the second chemistry for RIE, according to some embodiments of the present disclosure, a variety of material compositions for the metal mask layer were tested, including (in terms of atomic percentages for atomic composition): W(Si) with 60% tungsten to 40% silicon; W(Si) N with 75% tungsten, 12% silicon, and 13% nitrogen; W(Si) N with 61% tungsten, 23% silicon, and 16% nitrogen; W(Si) N with 63% tungsten, 11% silicon, and 25% nitrogen; and W(Si) N with 57% tungsten, 2% silicon, and 41% nitrogen. Such experiments using same parameters for the first chemistry passivation and the second chemistry etching (i.e., the parameters shown in the table of FIG. 13 for example) for these tested metal mask layers, and comparing them, showed that the metal mask layer having the 60:40 composition of W(Si) performed the worst having a lot of pitting and some bowing from lateral etching, next better was the 75:12:13 composition of W(Si) N having some pitting and some bowing, next better was 61:23:16 composition of W(Si) N, next better was the 63:11:25 composition of W(Si) N, and the best results of this group was the 57:2:41 composition of W(Si) N, in terms of smooth sidewalls, uniformity of circularity, and uniformity of critical dimensions across different hole depths. However, this same group of metal mask layer compositions has the opposite trend in terms of best to worst for providing etch selectivity of the substrate relative to the metal mask layer for subsequent etches typically used to pattern and etch the substrate using the metal mask layer (i.e., the 60:40 composition of W(Si) providing best etch selectivity and the 57:2:41 composition of W(Si) N providing the worst etch selectivity, relatively speaking). Thus, when selecting the material composition of the metal mask layer, there can be a tradeoff between providing a best results for patterning and etching the metal masking layer including tungsten and silicon using the first chemistry passivation and the second chemistry etching, according to some embodiments of the present disclosure, and providing the best etch selectivity between the substrate and the metal mask layer for subsequent patterning and etching of the substrate using the metal mask layer as a metal hard mask structure. Accordingly, considering such tradeoffs, for some applications, the 63:11:25 composition of W(Si) N can provide a best or optimum selection for the material of the metal mask layer, when using an embodiment of the present disclosure, with the 61:23:16 composition of W(Si) N being a close second place. However, many other possible compositions of the metal mask layer (e.g., other tungsten-containing materials) can be optimum for other applications, other substrate materials, other geometry sizes/densities, and/or other tuning of the first chemistry for passivation and the second chemistry for etching, according to some embodiments of the present disclosure.

Accordingly, in some embodiments, the metal mask layer can contain 55-70% tungsten. In some embodiments, the metal mask layer can contain 4-26% silicon. In some embodiments, the metal mask layer can contain 10-40% nitrogen. In some embodiments, the metal mask layer can contain 59-63% tungsten, 21-25% silicon, and 14-18% nitrogen. In some embodiments, the metal mask layer can contain 61-65% tungsten, 9-13% silicon, and 23-27% nitrogen.

In some embodiments, the first chemistry can have a gas flow rate ratio of sulfur dioxide to hydrogen of 5:1. In some embodiments, the second chemistry can have a gas flow rate ratio of boron trichloride to chlorine of 1:9. In some embodiments, a carrier gas for the first chemistry and/or the second chemistry can be a noble gas, such as Ar, He, Kr, Xe, or any combination thereof. In the experiments discussed herein, argon was used as carrier gas for the first chemistry and the second chemistry, for example.

Some experiments, using the variety of metal mask materials listed above, showed some example optimum ranges for the first chemistry and the second chemistry (using a same test pattern) as follows: a range of 65 to 85 SCCM for SO₂ in the first chemistry; a range of 10 to 17 SCCM for H₂ in the first chemistry; a range of 5 to 20 SCCM for BCl₃ in the second chemistry; and a range of 130 to 230 SCCM for Cl₂ in the second chemistry.

Generally, as the sizing of the holes shrinks (e.g., critical dimensions smaller) and/or pattern density increases, the passivation and/or etching using the first chemistry and the second chemistry according to an embodiment of the present disclosure may provide better results with relatively higher flow rates (SCCM) compared to the examples discussed above regarding the experiments.

In some embodiments, the etching with the second chemistry can be performed using a pulsing technique, with a range of frequencies of 0.1 kHz to 1 KHz, and with a range of duties of 20% to 40%, for example. Such pulsing technique can be performed under relatively low pressure, such as in a range of 10 mT to 30 mT (with lower ends of that range typically being optimum), for example. Typically, the pulse is only for low-frequency (LF) power, and not pulsing (keeping constant or closer to constant) for high-frequency (HF) power. Whereas, the passivation operations using the first chemistry can be a continuous wave (CW) process that has relatively high pressure in a range of 100 mT to 300 mT (with 100 mT typically showing better or best performance), for example.

Thus, in accordance with an embodiment of the present disclosure, optimizing the first chemistry and the second chemistry together, for a given hole dimension sizing (diameter and depth), pattern density, and a given material selected for metal mask layer, can provide the best or optimum results for forming the holes uniformly consistently in the metal mask layer, while also providing acceptable etch selectivity of the substrate relative to the metal mask layer in subsequent operations.

FIG. 13 illustrates a flow chart implementing the etching of a metal hard mask in accordance with an embodiment of the present disclosure.

In an embodiment, a method for forming a semiconductor device includes receiving a substrate having a metal mask layer thereon and a first mask layer over the metal mask layer, where the first mask layer is patterned having holes that open to the metal mask layer, and where the metal mask layer can contain tungsten, silicon, and nitrogen (box 1310). The method includes passivating a surface of the metal mask layer in the holes using a first chemistry to form a passivation layer on the surface of the metal mask layer, where the first chemistry can contain sulfur and hydrogen (box 1320). The method includes performing an anisotropic etch with a second chemistry to remove first passivation portions of the passivation layer and first metal portions of the metal mask layer at bottoms of the holes to increase hole depths of the holes in the metal mask layer, and where the second chemistry can contain boron and chlorine (box 1330).

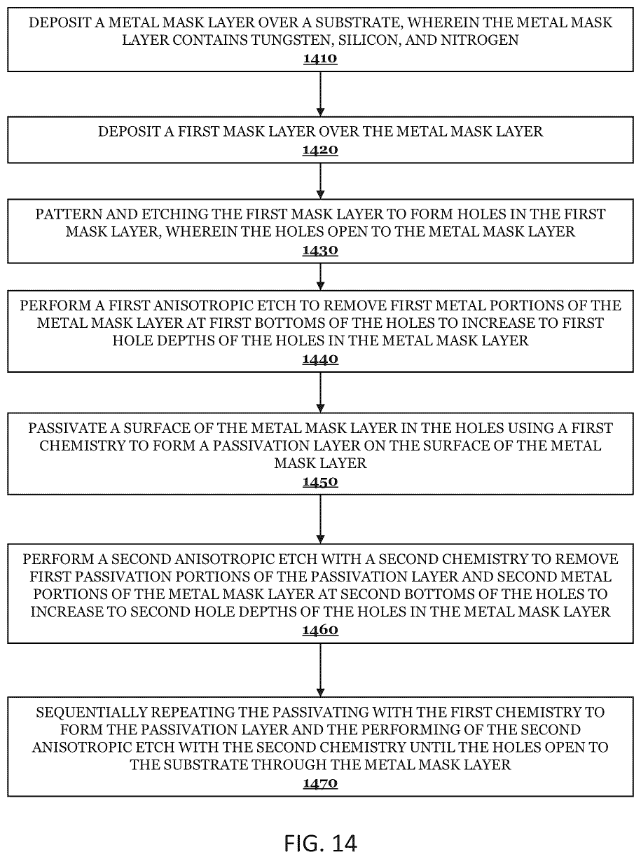

FIG. 14 illustrates a flow chart implementing the etching of a metal hard mask in accordance with an embodiment of the present disclosure.

In an embodiment, a method for forming a semiconductor device includes depositing a metal mask layer over a substrate, where the metal mask layer can contain tungsten, silicon, and nitrogen (box 1410). The method includes depositing a first mask layer over the metal mask layer (box 1420). The method includes patterning and etching the first mask layer to form holes in the first mask layer, where the holes open to the metal mask layer (box 1430). The method includes performing a first anisotropic etch to remove first metal portions of the metal mask layer at first bottoms of the holes to increase to first hole depths of the holes in the metal mask layer (box 1440). The method includes passivating a surface of the metal mask layer in the holes using a first chemistry to form a passivation layer on the surface of the metal mask layer, where the first chemistry can contain sulfur, oxygen, and hydrogen (box 1450). The method includes performing a second anisotropic etch with a second chemistry to remove first passivation portions of the passivation layer and second metal portions of the metal mask layer at second bottoms of the holes to increase to second hole depths of the holes in the metal mask layer, where second passivation portions of the passivation layer remain on at least part of sidewalls of the holes after the second anisotropic etch, where the second chemistry can contain boron and chlorine, and where the second hole depths are greater than the first hole depths (box 1460). The method includes sequentially repeating the passivating with the first chemistry to form the passivation layer and the performing of the second anisotropic etch with the second chemistry until the holes open to the substrate through the metal mask layer (box 1470).

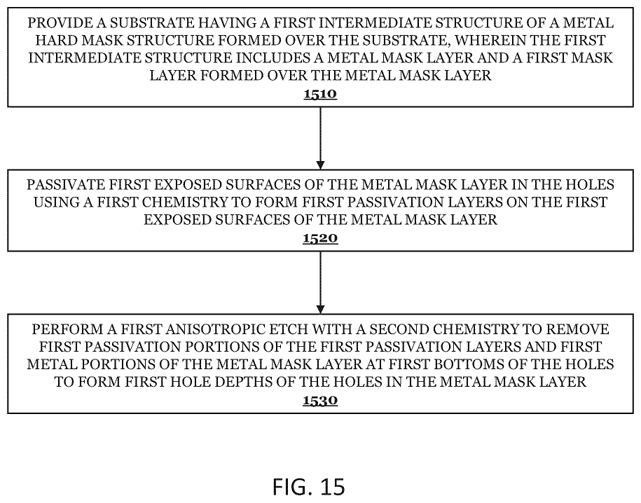

FIG. 15 illustrates a flow chart implementing the etching of a metal hard mask in accordance with an embodiment of the present disclosure.

In an embodiment, a method for forming a semiconductor device includes providing a substrate having a first intermediate structure of a metal hard mask structure formed over the substrate, where the first intermediate structure includes a metal mask layer and a first mask layer formed over the metal mask layer, where the first mask layer of the first intermediate structure is patterned to have holes through the first mask layer and partially into to the metal mask layer, where the metal mask layer can contain W(Si) N (box 1510). The method includes passivating first exposed surfaces of the metal mask layer in the holes using a first chemistry to form first passivation layers on the first exposed surfaces of the metal mask layer, where the first chemistry is formed by flowing a first gas mixture that can contain SO₂ and H₂ (box 1520). The method includes performing a first anisotropic etch with a second chemistry to remove first passivation portions of the first passivation layers and first metal portions of the metal mask layer at first bottoms of the holes to form first hole depths of the holes in the metal mask layer, where second passivation portions of the first passivation layers remain on at least part of sidewalls of the holes after the first anisotropic etch, to form a second intermediate structure of the metal hard mask structure, where the second chemistry is formed by flowing a second gas mixture that contain BCl₃ and Cl₂ (box 1530).

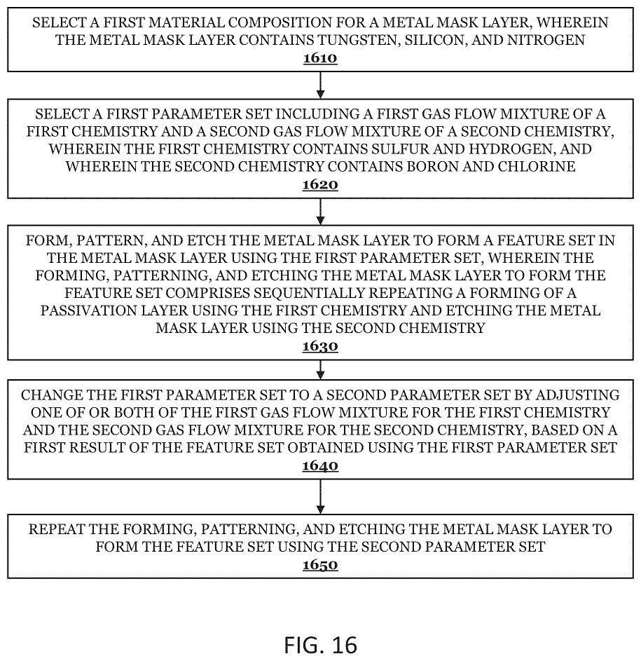

FIG. 16 illustrates a flow chart implementing the etching of a metal hard mask in accordance with an embodiment of the present disclosure.

In an embodiment, a method for forming a semiconductor device includes selecting a first material composition for a metal mask layer, where the metal mask layer contains tungsten, silicon, and nitrogen (box 1610). The method includes selecting a first parameter set including a first gas flow mixture of a first chemistry and a second gas flow mixture of a second chemistry, where the first chemistry can contain sulfur, oxygen, and hydrogen, and where the second chemistry can contain boron and chlorine (box 1620). The method includes forming, patterning, and etching the metal mask layer to form a feature set in the metal mask layer using the first parameter set, where the forming, patterning, and etching the metal mask layer to form the feature set comprises sequentially repeating a forming of a passivation layer using the first chemistry and etching the metal mask layer using the second chemistry (box 1630). The method includes changing the first parameter set to a second parameter set by adjusting one of or both of the first gas flow mixture for the first chemistry and the second gas flow mixture for the second chemistry, based on a first result of the feature set obtained using the first parameter set (box 1640). The method includes repeating the forming, patterning, and etching the metal mask layer to form the feature set using the second parameter set (box 1650).

The embodiments described in FIGS. 13-16 may be implemented as further described using FIGS. 1-12.

More example embodiments of the present disclosure are summarized here. Other embodiments can also be understood from the entirety of the specification as well as the claims filed herein.

Example 1. A method for forming a semiconductor device, the method including: receiving a substrate having a metal mask layer thereon and a first mask layer over the metal mask layer, where the first mask layer is patterned having holes that open to the metal mask layer, and where the metal mask layer contains tungsten, silicon, and nitrogen; passivating a surface of the metal mask layer in the holes using a first chemistry to form a passivation layer on the surface of the metal mask layer, where the first chemistry contains sulfur and hydrogen; and performing an anisotropic etch with a second chemistry to remove first passivation portions of the passivation layer and first metal portions of the metal mask layer at bottoms of the holes to increase hole depths of the holes in the metal mask layer, and where the second chemistry contains boron and chlorine.

Example 2. The method of example 1, where second passivation portions of the passivation layer remain on at least part of sidewalls of the holes after the anisotropic etch.

Example 3. The method of one of examples 1 or 2, where the first chemistry is formed by flowing a first gas mixture containing sulfur dioxide (SO₂) and hydrogen (H₂).

Example 4. The method of one of examples 1 to 3, where the second chemistry is formed by flowing a second gas mixture containing boron trichloride (BCl₃) and chlorine (Cl₂).

Example 5. The method of one of examples 1 to 4, where the first chemistry is formed by flowing a first gas mixture containing sulfur dioxide (SO₂) and hydrogen (H₂), and where the second chemistry is formed by flowing a second gas mixture containing boron trichloride (BCl₃) and chlorine (Cl₂).

Example 6. The method of one of examples 1 to 5, where the anisotropic etch includes bombarding the passivation layer at the bottoms of the holes with ions traveling perpendicular to the substrate.

Example 7. The method of one of examples 1 to 6, where the second chemistry is selective to etch the metal mask layer stronger than the passivation layer.

Example 8. The method of one of examples 1 to 7, where the performing of the anisotropic etch includes reactive ion etching.

Example 9. The method of one of examples 1 to 8, where the metal mask layer contains 59-63% tungsten, 21-25% silicon, and 14-18% nitrogen.

Example 10. The method of one of examples 1 to 9, where the metal mask layer contains 61-65% tungsten, 9-13% silicon, and 23-27% nitrogen.

Example 11. The method of one of examples 1 to 10, where a carrier gas for the first chemistry and the second chemistry includes one of or any combination of Ar, He, Kr, and Xe.

Example 12. A method for forming a semiconductor device, the method including: depositing a metal mask layer over a substrate, where the metal mask layer contains tungsten, silicon, and nitrogen; depositing a first mask layer over the metal mask layer; patterning and etching the first mask layer to form holes in the first mask layer, where the holes open to the metal mask layer; performing a first anisotropic etch to remove first metal portions of the metal mask layer at first bottoms of the holes to increase to first hole depths of the holes in the metal mask layer; passivating a surface of the metal mask layer in the holes using a first chemistry to form a passivation layer on the surface of the metal mask layer, where the first chemistry contains sulfur, oxygen, and hydrogen; performing a second anisotropic etch with a second chemistry to remove first passivation portions of the passivation layer and second metal portions of the metal mask layer at second bottoms of the holes to increase to second hole depths of the holes in the metal mask layer, where second passivation portions of the passivation layer remain on at least part of sidewalls of the holes after the second anisotropic etch, where the second chemistry contains boron and chlorine, and where the second hole depths are greater than the first hole depths; and sequentially repeating the passivating with the first chemistry to form the passivation layer and the performing of the second anisotropic etch with the second chemistry until the holes open to the substrate through the metal mask layer.

Example 13. The method of example 12, where the depositing of the metal mask layer includes physical vapor deposition.

Example 14. The method of one of examples 12 or 13, where the second anisotropic etch includes reactive ion etching by bombarding the passivation layer and the metal mask layer with ions traveling perpendicular to a top surface of the metal mask layer.

Example 15. The method of one of examples 12 to 14, where the second chemistry is selective to etch the metal mask layer stronger than the passivation layer.

Example 16. The method of one of examples 12 to 15, where the metal mask layer contains 59-63% tungsten, 21 25% silicon, and 14-18% nitrogen.

Example 17. The method of one of examples 12 to 16, where the metal mask layer contains 61-65% tungsten, 9-13% silicon, and 23-27% nitrogen.

Example 18. The method of one of examples 12 to 17, where the first chemistry is formed by flowing a first gas mixture containing sulfur dioxide (SO₂) and hydrogen (H₂); where the second chemistry is formed by flowing a second gas mixture containing boron trichloride (BCl₃) and chlorine (Cl₂); and where a carrier gas for the first chemistry and the second chemistry contains Ar.

Example 19. A method for forming a semiconductor device, the method including: providing a substrate having a first intermediate structure of a metal hard mask structure formed over the substrate, where the first intermediate structure includes a metal mask layer and a first mask layer formed over the metal mask layer, where the first mask layer of the first intermediate structure is patterned to have holes through the first mask layer and partially into to the metal mask layer, where the metal mask layer contains W(Si) N; passivating first exposed surfaces of the metal mask layer in the holes using a first chemistry to form first passivation layers on the first exposed surfaces of the metal mask layer, where the first chemistry is formed by flowing a first gas mixture containing SO₂ and H₂; and performing a first anisotropic etch with a second chemistry to remove first passivation portions of the first passivation layers and first metal portions of the metal mask layer at first bottoms of the holes to form first hole depths of the holes in the metal mask layer, where second passivation portions of the first passivation layers remain on at least part of sidewalls of the holes after the first anisotropic etch, to form a second intermediate structure of the metal hard mask structure, where the second chemistry is formed by flowing a second gas mixture containing BCl₃ and Cl₂.

Example 20. The method of example 19, further including: passivating second exposed surfaces of the metal mask layer in the holes of the second intermediate structure using the first chemistry to form second passivation layers on the second exposed surfaces of the metal mask layer; and performing a second anisotropic etch with the second chemistry to remove third passivation portions of the second passivation layers and second metal portions of the metal mask layer at second bottoms of the holes to form second hole depths of the holes in the metal mask layer, where fourth passivation portions of the second passivation layers remain on at least part of the sidewalls of the holes after the second anisotropic etch, to form a third intermediate structure of the metal hard mask structure, where the second hole depths of the third intermediate structure are greater than the first hole depths of the second intermediate structure.

Example 21. A method for selecting manufacturing parameters for forming a semiconductor device, the method including: selecting a first material composition for a metal mask layer, where the metal mask layer contains tungsten, silicon, and nitrogen; selecting a first parameter set including a first gas flow mixture of a first chemistry and a second gas flow mixture of a second chemistry, where the first chemistry contains sulfur, oxygen, and hydrogen, and where the second chemistry contains boron and chlorine; forming, patterning, and etching the metal mask layer to form a feature set in the metal mask layer using the first parameter set, where the forming, patterning, and etching the metal mask layer to form the feature set includes sequentially repeating a forming of a passivation layer using the first chemistry and etching the metal mask layer using the second chemistry; changing the first parameter set to a second parameter set by adjusting one of or both of the first gas flow mixture for the first chemistry and the second gas flow mixture for the second chemistry, based on a first result of the feature set obtained using the first parameter set; and repeating the forming, patterning, and etching the metal mask layer to form the feature set using the second parameter set.

Example 22. The method of example 21, further including: changing the first material composition to a second material composition for the metal mask layer, based on a second result of the feature set obtained using the second parameter set; repeating the forming, patterning, and etching the metal mask layer to form the feature set using the second parameter set and the second material composition for the metal mask layer; changing the second parameter set to a third parameter set by adjusting one of or both of the first gas flow mixture for the first chemistry and the second gas flow mixture for the second chemistry, based on a third result of the feature set obtained using the second parameter set and the second material composition for the metal mask layer; and repeating the forming, patterning, and etching the metal mask layer to form the feature set using the third parameter set and the second material composition for the metal mask layer.

Example 23. The method of one of examples 21 or 22, where the first parameter set includes a first volumetric flowrate of sulfur-containing gas for the first chemistry, a second volumetric flowrate of hydrogen-containing gas for the first chemistry, a third volumetric flowrate of boron-containing gas for the second chemistry, and a fourth volumetric flowrate of chlorine-containing gas for the second chemistry; and where the first material composition for the metal mask layer contains 61-65% tungsten, 9-13% silicon, and 23-27% nitrogen.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

1. A method for forming a semiconductor device, the method comprising:
receiving a substrate having a metal mask layer thereon and a first mask layer over the metal mask layer, wherein the first mask layer is patterned having holes that open to the metal mask layer, and wherein the metal mask layer contains tungsten, silicon, and nitrogen;
passivating a surface of the metal mask layer in the holes using a first chemistry to form a passivation layer on the surface of the metal mask layer, wherein the first chemistry contains sulfur and hydrogen; and
performing an anisotropic etch with a second chemistry to remove first passivation portions of the passivation layer and first metal portions of the metal mask layer at bottoms of the holes to increase hole depths of the holes in the metal mask layer, and wherein the second chemistry contains boron and chlorine.

2. The method of claim 1, wherein second passivation portions of the passivation layer remain on at least part of sidewalls of the holes after the anisotropic etch.

3. The method of claim 1, wherein the first chemistry is formed by flowing a first gas mixture containing sulfur dioxide (SO₂) and hydrogen (H₂).

4. The method of claim 3, wherein the second chemistry is formed by flowing a second gas mixture containing boron trichloride (BCl₃) and chlorine (Cl₂).

5. The method of claim 1, wherein the second chemistry is formed by flowing a second gas mixture containing boron trichloride (BCl₃) and chlorine (Cl₂).

6. The method of claim 1, wherein the anisotropic etch includes bombarding the passivation layer at the bottoms of the holes with ions traveling perpendicular to the substrate.

7. The method of claim 1, wherein the second chemistry is selective to etch the metal mask layer stronger than the passivation layer.

8. The method of claim 1, wherein the performing of the anisotropic etch includes reactive ion etching.

9. The method of claim 1, wherein the metal mask layer contains 59-63% tungsten, 21-25% silicon, and 14-18% nitrogen.

10. The method of claim 1, wherein the metal mask layer contains 61-65% tungsten, 9-13% silicon, and 23-27% nitrogen.

11. The method of claim 1, wherein a carrier gas for the first chemistry and the second chemistry comprises one of or any combination of Ar, He, Kr, and Xe.

12. A method for forming a semiconductor device, the method comprising:
depositing a metal mask layer over a substrate, wherein the metal mask layer contains tungsten, silicon, and nitrogen;
depositing a first mask layer over the metal mask layer;
patterning and etching the first mask layer to form holes in the first mask layer, wherein the holes open to the metal mask layer;
performing a first anisotropic etch to remove first metal portions of the metal mask layer at first bottoms of the holes to increase to first hole depths of the holes in the metal mask layer;
passivating a surface of the metal mask layer in the holes using a first chemistry to form a passivation layer on the surface of the metal mask layer, wherein the first chemistry contains sulfur, oxygen, and hydrogen;
performing a second anisotropic etch with a second chemistry to remove first passivation portions of the passivation layer and second metal portions of the metal mask layer at second bottoms of the holes to increase to second hole depths of the holes in the metal mask layer, wherein second passivation portions of the passivation layer remain on at least part of sidewalls of the holes after the second anisotropic etch, wherein the second chemistry contains boron and chlorine, and wherein the second hole depths are greater than the first hole depths; and
sequentially repeating the passivating with the first chemistry to form the passivation layer and the performing of the second anisotropic etch with the second chemistry until the holes open to the substrate through the metal mask layer.

13. The method of claim 12, wherein the depositing of the metal mask layer includes physical vapor deposition.

14. The method of claim 12, wherein the second anisotropic etch includes reactive ion etching by bombarding the passivation layer and the metal mask layer with ions traveling perpendicular to a top surface of the metal mask layer.

15. The method of claim 12, wherein the second chemistry is selective to etch the metal mask layer stronger than the passivation layer.

16. The method of claim 12, wherein the metal mask layer contains 59-63% tungsten, 21-25% silicon, and 14-18% nitrogen.

17. The method of claim 12, wherein the metal mask layer contains 61-65% tungsten, 9-13% silicon, and 23-27% nitrogen.

18. The method of claim 12, wherein the first chemistry is formed by flowing a first gas mixture containing sulfur dioxide (SO₂) and hydrogen (H₂);
wherein the second chemistry is formed by flowing a second gas mixture containing boron trichloride (BCl₃) and chlorine (Cl₂); and
wherein a carrier gas for the first chemistry and the second chemistry contains Ar.

19. A method for forming a semiconductor device, the method comprising:
providing a substrate having a first intermediate structure of a metal hard mask structure formed over the substrate, wherein the first intermediate structure includes a metal mask layer and a first mask layer formed over the metal mask layer, wherein the first mask layer of the first intermediate structure is patterned to have holes through the first mask layer and partially into to the metal mask layer, wherein the metal mask layer contains W(Si) N;
passivating first exposed surfaces of the metal mask layer in the holes using a first chemistry to form first passivation layers on the first exposed surfaces of the metal mask layer, wherein the first chemistry is formed by flowing a first gas mixture containing SO₂ and H₂; and
performing a first anisotropic etch with a second chemistry to remove first passivation portions of the first passivation layers and first metal portions of the metal mask layer at first bottoms of the holes to form first hole depths of the holes in the metal mask layer, wherein second passivation portions of the first passivation layers remain on at least part of sidewalls of the holes after the first anisotropic etch, to form a second intermediate structure of the metal hard mask structure, wherein the second chemistry is formed by flowing a second gas mixture containing BCl₃ and Cl₂.

20. The method of claim 19, further comprising:
passivating second exposed surfaces of the metal mask layer in the holes of the second intermediate structure using the first chemistry to form second passivation layers on the second exposed surfaces of the metal mask layer; and
performing a second anisotropic etch with the second chemistry to remove third passivation portions of the second passivation layers and second metal portions of the metal mask layer at second bottoms of the holes to form second hole depths of the holes in the metal mask layer, wherein fourth passivation portions of the second passivation layers remain on at least part of the sidewalls of the holes after the second anisotropic etch, to form a third intermediate structure of the metal hard mask structure, wherein the second hole depths of the third intermediate structure are greater than the first hole depths of the second intermediate structure.
